(19) United States
(12) Patent Application Publication
(10) Pub. No.: US 2026/0353883 A1
(43) Pub. Date: Nov. 5, 2026

(54) DISPLAY PANEL AND DISPLAY DEVICE

(71) Applicant: WUHAN CHINA STAR OPTOELECTRONICS TECHNOLOGY CO., LTD., Wuhan, Hubei (CN)

(72) Inventors: Yong YANG, Wuhan, Hubei (CN); Fancheng LIU, Wuhan, Hubei (CN); Guowei ZHA, Wuhan, Hubei (CN); Zhou ZHOU, Wuhan, Hubei (CN)

(73) Assignee: WUHAN CHINA STAR OPTOELECTRONICS TECHNOLOGY CO., LTD., Wuhan, Hubei (CN)

(21) Appl. No.: 18/995,070

(22) PCT Filed: Nov. 21, 2023
(86) PCT No.: PCT/CN2023/132998

§ 371 Date: Jan. 15, 2025

(30) Foreign Application Priority Data
Sep. 26, 2023 (CN) 202311258828.2

(51) Int. Cl. H10H 29/39; H10H 29/49

(52) U.S. Cl. CPC H10H 29/39; H10H 29/49

(57) ABSTRACT

Disclosed herein is a display panel and a display device. The display panel includes an array substrate, with a plurality of pixel driving circuits provided on the array substrate; a plurality of light-emitting units, the plurality of light-emitting units are provided in an array on the array substrate, each of the light-emitting units includes a plurality of light-emitting chips, the plurality of light-emitting chips comprise a first light-emitting chip, a second light-emitting chip and a third light-emitting chip; and a number of the light-emitting chips contained in any one of the light-emitting units is greater than the colours types of the light-emitting chips.

### TECHNICAL FIELD

The present application relates to the field of display technology, and specifically to a display panel and a display device.

### BACKGROUND

MLED (Mini/Micro LED) direct display technology has received more and more attention recently, and it has many advantages such as high brightness, high contrast, high resolution, good reliability, and the ability to produce a flexible display and which is well recognized as a next generation display technology. However, MLED still faces a large challenge in terms of design, process, driving, and optics. Based on the current light-emitting characteristics of the inorganic microLED, the instability of the efficiency thereof requires the TFT in the driver circuit to work in the saturation region, resulting in a large power loss of the direct display substrate circuit and a correspondingly large power loss of the entire system.

### SUMMARY

Embodiments of the present application provide a display panel and a display device, such that when a plurality of light-emitting chips are connected, the number of the connected components in the pixel driving circuit is increased, the current is decreased, and a proportion of the power consumption of the light-emitting chip portion is increased in the power consumption of the panel, reducing the overall power consumption of the panel.

In a first aspect, embodiments of the present application provide a display panel, including:
an array substrate, where a plurality of pixel driving circuits are provided on the array substrate;
a plurality of light-emitting units, where the plurality of the light-emitting units are provided in an array on the array substrate, each of the light-emitting units include a plurality of light-emitting chips, the plurality of light-emitting chips include a first light-emitting chip, a second light-emitting chip and a third light-emitting chip, the first light-emitting chip, the second light-emitting chip and the third light-emitting chip have different colours different from each other; a number of the light-emitting chips contained in any one of the light-emitting unit is greater than a number of colour types of the light-emitting chips; light-emitting chips having the same colours in each of the light-emitting unit are connected in series, and the light-emitting chips having the same colours in each of the light-emitting units are electrically connected to one of the pixel driving circuits;
The first light-emitting chip provides a blue light, the second light-emitting chip provides a red light, and the third light-emitting chip provides a green light; each of the light-emitting unit includes one the first light-emitting chip, at least one the second light-emitting chip, and at least one the third light-emitting chip;
The first light-emitting chip, the second light-emitting chip and the third light-emitting chip in the light-emitting units are alternately arranged.

In a first aspect, embodiments of the present application provide a display panel, including:
an array substrate, where a plurality of pixel driving circuits are provided on the array substrate;
a plurality of light-emitting units, where the plurality of the light-emitting units are provided in an array on the array substrate, each of the light-emitting unit includes a plurality of light-emitting chips, the plurality of light-emitting chips include a first light-emitting chip, a second light-emitting chip and a third light-emitting chip, the first light-emitting chip, the second light-emitting chip and the third light-emitting chip have colours different from each other; a number of the light-emitting chips contained in any one of the light-emitting units is greater than a number of colour types of the light-emitting chips; the light-emitting chips having the same colours in each of the light-emitting units are connected in series, and the light-emitting chips having the same colours in each of the light-emitting units are electrically connected to one of the pixel driving circuits.

In a third aspect, the present application provides a display device, which includes the display panel as described in any one of the above.

### BRIEF DESCRIPTION OF THE DRAWINGS

The technical solutions and other beneficial effects of the present application will be apparent through a detailed description of the specific embodiments of the present application in conjunction with the accompanying drawings.

FIG. 1 is a schematic structural diagram of a display panel in an embodiment of the present application;

FIG. 2 is a schematic connection diagram of a light-emitting chip in the display panel in another embodiment of the present application;

FIG. 3 is a schematic connection diagram of components of a display panel in an embodiment of the present application;

FIG. 4 is a schematic diagram of a current efficiency for a red light-emitting chip in an embodiment of the present application;

FIG. 5 is a schematic diagram of a 3T1C pixel driving circuit in an embodiment of the present application;

FIG. 6 is a driving timing diagram of the 3T1C pixel driving circuit shown in FIG. 4 of the present application;

FIG. 7 is a schematic diagram of an 8T1C pixel driving circuit in an embodiment of the present application;

FIG. 8 is a driving timing diagram of the 8T1C pixel driving circuit shown in FIG. 6 of the present application;

FIG. 9 is a schematic diagram of a 7T2C pixel driving circuit in an embodiment of the present application;

FIG. 10 is a driving timing diagram detected by the 7T2C pixel driving circuit T2 shown in FIG. 7 of the present application;

FIG. 11 is a driving timing diagram detected by the 7T2C pixel driving circuit T4 shown in FIG. 7 of the present application;

FIG. 12 is a schematic diagram of a colour coordinate of a green light-emitting chip in another embodiment of the present application;

FIG. 13 is a schematic diagram of a manufacturing process flow chart of a direct display sample in an embodiment of the present application.

### REFERENCE SYMBOLS

1. Array substrate; 2. Light-emitting unit; 21. First light-emitting chip; 22. Second light-emitting chip; 23. Third light-emitting chip.

### DETAILED DESCRIPTION

The technical solutions in the embodiments of the present application will be clearly and completely described below with reference to the accompanying drawings in the embodiments of the present application. Obviously, the described embodiments are only some of the embodiments of the present application, but not all of the embodiments. Based on the embodiments in the present application, all other embodiments obtained by those skilled in the art without making creative efforts fall within the scope of protection of the present application.

In the description of the present application, it is to be understood that the orientations or positional relationships indicated by the terms “centre”, “longitudinal”, “transversal”, “length”, “width”, “thickness”, “upper”, “lower”, “front”, “back”, “left”, “right”, “vertical”, “horizontal”, “top”, “bottom”, “inner”, “outer”, “clockwise”, “counter clockwise” and the like are the orientations or positional relationships shown based on the drawings. They are only for the convenience of describing the present application and simplifying the description, without indicating or implying that the referred device or element must have a specific orientation, are constructed and operated in a specific orientation and therefore should not be construed as limiting the present application. In addition, the terms “first” and “second” are only used for descriptive purpose and cannot be understood as indicating or implying relative importance or implicitly indicating the quantity of the indicated technical features. Therefore, the features defined by “first” and “second” may explicitly or implicitly include one or more of the features. In the description of the present application, “plurality of” means two or more, unless otherwise clearly and specifically limited.

In the description of this application, it should be noted that, unless otherwise clearly specified and limited, the terms “installation”, “connected” and “connection” should be understood in a broad sense. For example, it may either a fixed connection or a detachable connection, or integral connection; it may be a mechanical connection, an electrical connection or a mutual communication; it may be direct connection, or indirect connection through an intermediary, it maybe the internal communication inside two elements or the interaction relationship between two elements. For those of ordinary skill in the art, the specific meanings of the above terms in the present application may be understood according to the specific circumstances.

In the present application, unless otherwise expressly specified and limited, the first feature being “above” or “below” a second feature may include direct contact between the first and second features, or may also include the indirect contact between the first and second features but the contact through additional feature between them. Furthermore, the first feature being “above”, “on” and “over” a second feature includes the first feature being directly above and diagonally above the second feature, or simply mean that a horizontal height of the first feature is higher than that of the second feature. The first feature being “below”, “under” and “below” the second feature includes the first feature being directly below and diagonally below the second feature, or simply means that the horizontal height of the first feature is smaller than that of the second feature.

The following disclosure provides many different embodiments or examples for implementing the various structures of the present application. To simplify the disclosure of the present application, the components and arrangements of specific examples are described below. Of course, they are merely exemplary and are not intended to limit the application. Furthermore, the present application may repeat reference numbers and/or reference letters in different examples, such repetition being for the purposes of simplicity and clarity and does not by itself indicate a relationship between the various embodiments and/or arrangements as discussed. In addition, the present application provides examples of various specific processes and materials, but one of ordinary skill in the art will recognize the application of other processes and/or the use of other materials.

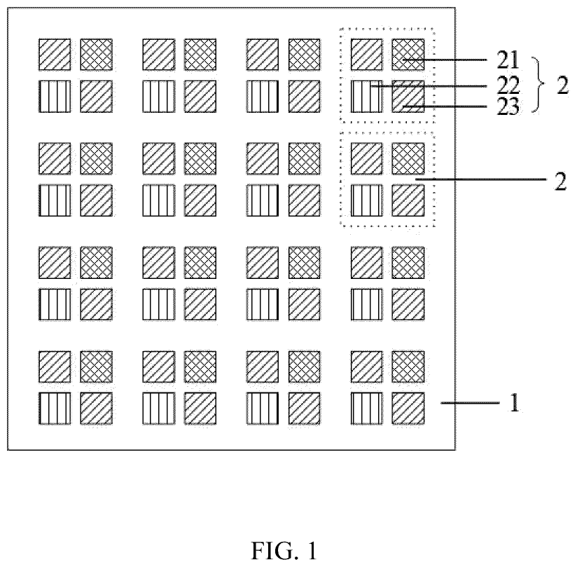

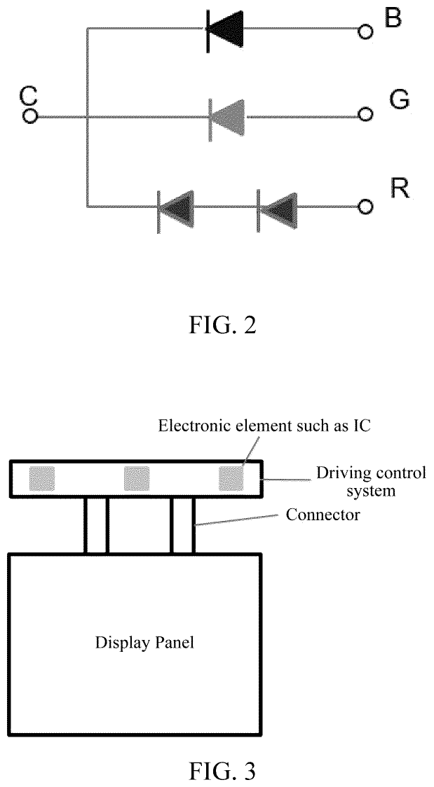

Referring to FIGS. 1 and 2, embodiments of the present application provide a display panel, the display panel includes an array substrate 1 and a plurality of light-emitting units 2 arranged in an array on the array substrate 1. The plurality of pixel driving circuits (not shown in the FIG.) is provided on the array substrate 1.

Each of the light-emitting units 2 include a plurality of light-emitting chips, the plurality of light-emitting chips include a first light-emitting chip 21, a second light-emitting chip 22, and a third light-emitting chip 23. The first light-emitting chip 21, the second light-emitting chip 22, and the third light-emitting chip 23 have colours different from each other. For example, the first light-emitting chip 21, the second light-emitting chip 22 and the third light-emitting chip 23 are respectively a blue light-emitting chip, a red light-emitting chip and a green light-emitting chip. The light-emitting chips having different colours of the light-emitting unit 2 cooperate to output pixel frames of different colours, that is, the light-emitting unit 2 are the smallest unit of the light-emitting chip combination. Based on the different light-emitting principle of the display panel, the light-emitting unit 2 may further include a fourth light-emitting chip-the white light-emitting chips etc., which are not specifically limited in the present embodiment.

The number of the light-emitting chips contained in the light-emitting unit 2 is greater than the number of the colour types of the light-emitting chips, that is, the number of the light-emitting chips having at least one colour in the light-emitting unit 2 is two or more. For example, the light-emitting unit 2 include the light-emitting chips having three colours which are a first light-emitting chip 21, a second light-emitting chip 22 and a third light-emitting chip 23, and, then the total number of the light-emitting chips contained in the light-emitting unit 2 is least four, the first light-emitting chip 21, the second light-emitting chip 22 and the third light-emitting chip 23 are the blue light-emitting chip, the red light-emitting chip and the green light-emitting chip respectively, and then the number of the blue light-emitting chip is 1, the number of the red light-emitting chips are 2 and the number of the green light-emitting chip is 1. The specific number of the light-emitting chips having three colours which are the first light-emitting chip 21, the second light-emitting chip 22 and the third light-emitting chip 23 is not specifically limited in the present embodiment.

The pixel driving circuit on the array substrate 1 is used to drive the light-emitting chips in the light-emitting unit 2 to emit the light. Since the light-emitting chips of different colours may have different luminance intensities, the light-emitting chips of different colours in the light-emitting unit 2 are electrically connected to one of the pixel driving circuit respectively. That is, the number of the pixel driving circuits connected to one light-emitting unit 2 is the same as the types of colours of the light-emitting chips contained in one light-emitting unit 2. For example, the light-emitting unit 2 includes the light-emitting chips having three colours which are a first light-emitting chip 21, a second light-emitting chip 22, and a third light-emitting chip 23, then the light-emitting unit 2 is electrically connected to three pixel driving circuits, the first light-emitting chip 21, the second light-emitting chip 22 and the third light-emitting chip 23 are respectively connected to one of the pixel driving circuits. In addition, the light-emitting chips having the same colour in the light-emitting unit 2 are connected in series, and are electrically connected to the same pixel driving circuit after being connected in series.

Compared with the case of only connecting one light-emitting chip, when the pixel driving circuit provided on the array substrate 1 in the present embodiment is connected to the plurality of light-emitting chips, the number of the connected components in the pixel driving circuit is increased and the current is decreased, but the proportion of the power consumption of the light-emitting chip portion is increased in the panel power consumption, the proportion of the power consumption of TFT (Thin Film Transistor) in the pixel driving circuit is deceased in the panel power consumption, thereby reducing the overall powder consumption of the panel.

In one embodiment, the light-emitting unit 2 is connected between the first voltage terminal VDD and the second voltage terminal VSS, so a part of the voltage difference between the first voltage terminal VDD and the second voltage terminal VSS is divided at both ends of the light-emitting chip, the other part is divided at both ends of the pixel driving circuit. However, when the light-emitting chip does not emit the light, the voltage difference between the first voltage terminal VDD and the second voltage terminal VSS is all applied to both ends of the pixel driving circuit. Therefore, due to the limitations of each component in the pixel driving circuit, the voltage difference value between the first voltage terminal VDD and the second voltage terminal VSS has a certain limit range, so the number of the light-emitting chips cannot be increased without limit. The maximum number of any one of the light-emitting chips in the light-emitting unit 2 is positively related to the pressure difference value between the first voltage terminal VDD and the second voltage terminal VSS. Further, the maximum number of any one of the light-emitting chips in the light-emitting unit 2 is the ratio of the voltage difference value between the first voltage terminal VDD and the second voltage terminal VSS to the voltage difference value between the light-emitting chips which is rounded to an integer. For example, the voltage difference value between the first voltage terminal VDD and the second voltage terminal VSS is 11V, and the voltage difference value between the light-emitting chips is 2V, so the maximum number of the light-emitting chips is 5.

In one embodiment, since compared to the red light-emitting chip (the voltage difference value of 1.8V) and the green light-emitting chip (the voltage difference value of 1.2V), the voltage difference value at two ends of the blue light-emitting chip (voltage difference value of 2.5V) under the same current is larger, the voltage division at both ends of the blue light-emitting chip is too large when the plurality of the blue light-emitting chips are connected in series in the pixel driving circuit. Under the premise that the voltage difference value between the first voltage terminal VDD and the second voltage terminal VSS is defined, the voltage difference value at two ends of the driving TFT in the driving circuit is too small which may result in failure to driving. Therefore, when the first light-emitting chip 21 is set to be the blue light-emitting chip, the light-emitting unit 2 only includes one first light-emitting chip 21. When the second light-emitting chip 22 is the red light-emitting chip, the number of the second light-emitting chip 22 is 2-6, and when the third light-emitting chip 23 is the green light-emitting chip, the number of the third light-emitting chip 23 is 2-4.

In one embodiment, the light-emitting unit 2 is the smallest unit of the light-emitting chip combination defined to facilitate the description. All the light-emitting chips in the display panel may be separately provided on the array substrate 1 respectively, or may also package the light-emitting chips for facilitating the requirement such as transfer and installation, i.e. packaging the light-emitting chips of at least one light-emitting unit 2 to obtain an LED packaging module, and installing the light-emitting chips in one LED packaging module as a whole. The light-emitting unit 2 further includes a substrate (not shown in the FIG.) and a packaging layer (not shown in the FIG.). The first light-emitting chip 21, the second light-emitting chip 22 and the third light-emitting chip 23 are bound to the substrate, and the packaging layer covers the first light-emitting chip, the second light-emitting chip and the third light-emitting chip, that is, the light-emitting unit 2 is packaged as a whole to facilitate mass transfer. It should be noted that the number of light-emitting chips contained in one light-emitting unit 2 is not specifically limited in the present embodiment.

The microLED chip lamp beads in package (MIP) are adopted for patching. Taking the R2GB encapsulated MIP lamp beads as the example, each lamp bead contains RGB three-colour chips. Each colour of the micro-chip on the encapsulated MIP lamp bead is controlled by the separate electrode, the monochrome chip is controlled by a separate set of circuits (the number of the transistors contained each set of circuits is 1-20), that is, each MIP lamp bead corresponds to three sets of circuits which control the RGB three-colour chips respectively. As shown in FIG. 3, the display panel is connected to the out-of-plane display control system through a connecting device (a connector, FPC, COF etc.), and the peripheral drive circuit system control realizes signal editing, control and in-plane transmission through IC.

In one embodiment, each light-emitting chip in the LED packaging module may be connected through separate wiring. However, in order to facilitate layout and reduce wiring, each light-emitting chip in the LED packaging module shares a common cathode or a common anode. As shown in FIG. 2, the three-colour chip uses a common cathode, and the anode at the other end is designed separately.

In one embodiment, since the light-emitting chips of at least one colour in one light-emitting unit 2 are set as two or more, in order to make the colour displayed in the light-emitting unit 2 uniform, the first light-emitting chip 21, the second light-emitting chip 22 and the third light-emitting chip 23 in the light-emitting unit 2 are arranged alternately, that is, in sought to ensure that any two adjacent light-emitting chips are not the same colour, and avoid that the two adjacent light-emitting chips are the same colour, resulting in a larger colour block having the same colour, affecting the display effect. The MIP packaged lamp bead structure is in the form of RnGmB (n: 2-6; m: 2-4), for example, there are 1 blue light-emitting chip, 2 red light-emitting chips, and 3 green light-emitting chips in one light-emitting unit. As shown in FIG. 1, the four light-emitting chips in the light-emitting unit 2 are arranged in a rectangle, and two light-emitting chips having the same colour are located at the diagonal positions of the rectangle. That is, taking R2GB as an example, the MIP packaged lamp bead contains 1 blue light micro-chip and green light micro-chip, as well as 2 red light micro-chips. As for the arrangement, the red light chip, the blue light and green light chips are arranged alternately. The connection manner is the parallel design between the RGB three-colour chips, and the 2 red light chips are designed in series.

In one embodiment, the pixel driving circuit includes a driving module, a switch module and a charge storage module. The driving module is connected in series with the light-emitting chip having the same colour in the light-emitting unit 2 between the first voltage terminal (VDD) and the second voltage terminal (VSS), and the driving module are electrically connected to the charge storage module, the first end of the switch module is connected to the scan signal, the second end of the switch module is connected to the data signal, the third end of the switch module is connected to the driving module and the charge storage module, and the scan signal controls the turn-on of the switch module to write the data signal into the charge storage module, so that the driving module drives the connected light-emitting chips to emit the light.

The driving module includes a driving TFT. The driving manner is TFT active matrix driving. The TFT transistor may be LTPS, LTPO or IGZO. The switch module includes at least one switching TFT, and the charge storage module includes at least one storage capacitor. Since the TFT transistor requires performing array film formation preparation, it is difficult to achieve the same electrical characteristics of each TFT due to a process fluctuation. Therefore, if the TFT operates in the linear region, the fluctuations in its electrical parameters will have a greater impact on the brightness and uniformity of LED lighting, so it is recommended that the TFT operates in the electrical saturation region. In the saturation region of TFT, the current changes with voltage in a smaller range which is beneficial to achieve uniform light emission of LEDs. Under a specific current and a certain pitch design, the power consumption of the panel in the saturation region is determined only by the cross-voltage between the first voltage terminal and the second voltage terminal. Since the cross-voltage of the TFT in the saturation region is also relatively constant, the panel power consumption in the saturation region is also relatively defined. Increasing the proportion of LED power consumption in the panel power consumption will help to improve the photoelectric conversion efficiency of microLED direct display.

Since the TFT transistors require performing the array film formation preparation, it is difficult to achieve the same electrical characteristics of each TFT due to the process fluctuation. Therefore, if the TFT operates in the linear region, the fluctuations in its electrical parameters will have a greater impact on the illuminous brightness and uniformity of the LED. Therefore, it is recommended that the TFT operates in the electrical saturation region. In the saturation region of TFT, the current changes with voltage in a smaller range which is beneficial to achieve uniform light emission of LEDs. Under a specific current and a certain pitch design, the power consumption of the panel in the saturation region is determined only by the cross-voltage between the first voltage terminal Vdd and the second voltage terminal Vss. Since the cross-voltage of the TFT in the saturation region is also relatively constant, the saturation The panel power consumption in this area is also relatively certain. Increasing the proportion of LED power consumption in panel power consumption will help improve the photoelectric conversion efficiency of microLED direct display. The arrangement manner using RnGmB can achieve increase in the proportion of LED power consumption. For example, when two R chips are connected in series, if the same brightness needs to be maintained, the driving current of the R chip may be reduced by half (the luminous efficiency is not considered), which significantly reduces the panel power consumption and increases the proportion of RGB power consumption; if the current of R is maintained unchanged, the panel power consumption remains unchanged, but the power consumption of the R chip doubles, the panel brightness is increased, and the proportion of the RGB chip power consumption is enhanced.

The simplest pixel driving circuit applicable to the present embodiment is 2T1C. The gate of the switching TFT is connected to the scanning signal, one end of the source and drain of the switching TFT is connected to the data signal, and the other end of the source and drain of the switching TFT is connected to the gate of the driving TFT, and one end of the storage capacitor, one end of the source and drain of the driving TFT is connected to the first voltage terminal, the other end of the source and drain of the driving TFT is connected to the other end of the storage capacitor and the anode of the light-emitting chip, and the cathode of the light-emitting chip is connected to the second voltage terminal. Therefore, compared with the case of connecting only one light-emitting chip, when multiple light-emitting chips are connected, the current flowing through the driving TFT and the light-emitting chip is reduced, and under the premise that the voltage difference value between the first voltage terminal and the second voltage terminal remains unchanged, the overall power consumption of the display panel is reduced, the voltage division at both ends of the driving TFT is reduced, the voltage division at both ends of the light-emitting chip is increased, and the proportion of the power consumption of the light-emitting chip portion is increased in the overall power consumption of the display panel.

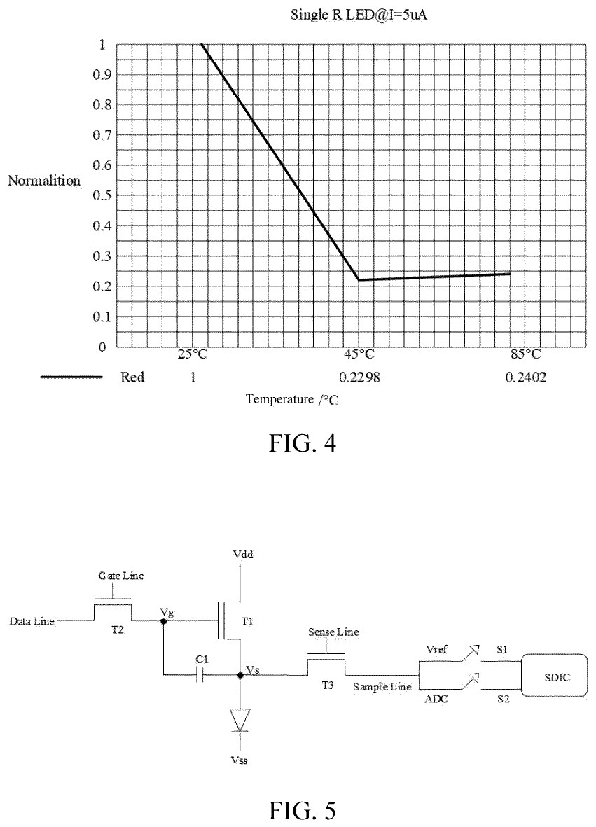

The more mature process of the red light chip in microLED chips does not use the InPAs light-emitting structure, and the material thereof has poor heat resistance stability, resulting in obvious brightness attenuation and colour shift phenomena of the chip during long-term use. Due to the red light LED characteristics, the current efficiency of LED will roll off at a high temperature, as shown in FIG. 4, which will thereby significantly affect the brightness and chromaticity of the display screen. As the luminous efficiency of the red LED decreases, most of the energy will be lost through heat generation. Reducing the operating current of the LED can effectively improve heating of the chip and stabilize the thermal efficiency of the chip. In the present embodiment, use of the manner that two or more red light-emitting chips are connected in series may effectively reduce their operating current.

The present application is based on microLED direct display technology. By adding one or more R and G sub-pixel designs to the conventional RGB pixel structure, it reduces the proportion of TFT power consumption in the panel power consumption, thereby reducing the overall power consumption of the panel; meanwhile, increasing the number of R chips in a pixel unit reduces the luminous current and heat generation of the single R chip and improves its luminous stability. Increasing the number of G chips in one pixel unit reduces the working current range of the G chip in the different driving modes of glass substrate and improves the colour shift of the G chip.

In one embodiment, the pixel driving circuit further includes a compensation module electrically connected to the driving module and the charge storage module. The compensation module is used to maintain a constant voltage value at two ends of the light-emitting chips electrically connected to the pixel driving circuit. The compensation module includes at least one compensation TFT.

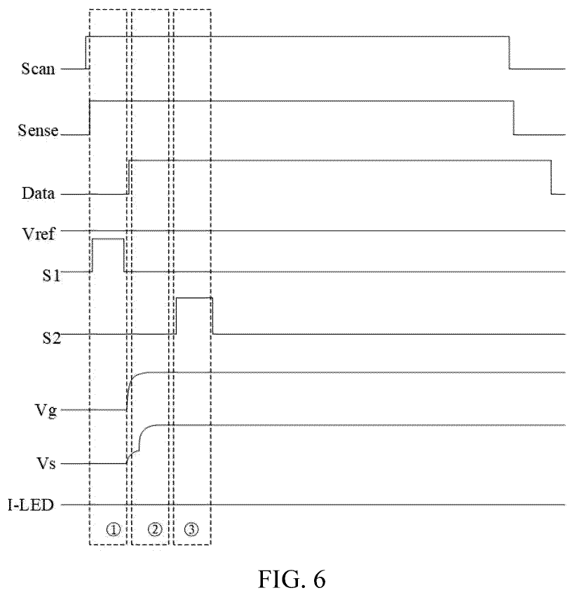

The 3T1C pixel driving circuit shown in FIG. 5 and FIG. 6 includes a driving TFT_T1, a switching TFT_T2, a compensation TFT_T3 and a storage capacitor C1. (1) Initialization stage: Gate Line & Sense Line has a high level, switch TFT_T2 and the compensation TFT_T3 are turned on, S1 is turned on, Vg=Vdata_L, Vs=Vref; (2) Vth storage stage: Gate Line & Sense Line is set high, switch TFT_T2 and compensation TFT_T3 are turned on, Vg=Vdata_H, driving TFT_T1 is turned on, S1 and S2 are turned on, Vs point is gradually charged from Vref to Vs=Vdata_H−Vth, Vth is the threshold voltage for driving TFT_T1; (3) Vth detection storage stage: S1 is turned off, S2 is turned on, Vref is not input, ADC (analog-to-digital converter) starts to detect data, Vgs=Vdata_H−Vs=Vdata_H−(Vdata_H−Vth)=Vth. Therefore, the compensation TFT_T3 makes the voltage value of the light-emitting chip portion constant.

On the basis that the voltage value of the light-emitting chip portion is constant, if the same brightness needs to be maintained, the driving current of the light-emitting chip is reduced to one n (n is the number of light-emitting chips, without considering the luminous efficiency), significantly reducing the panel power consumption and increasing the proportion of power consumption of the light-emitting chip portion; if the driving current of the light-emitting chip is kept unchanged, the power consumption of the panel remains unchanged, but the power consumption of the light-emitting chip becomes n times, the brightness of the panel is enhanced, and the proportion of the power consumption of the light-emitting chip portion is increased.

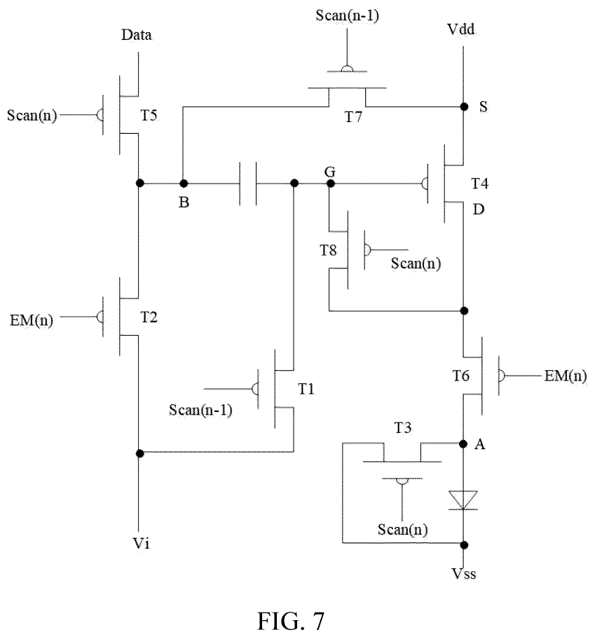

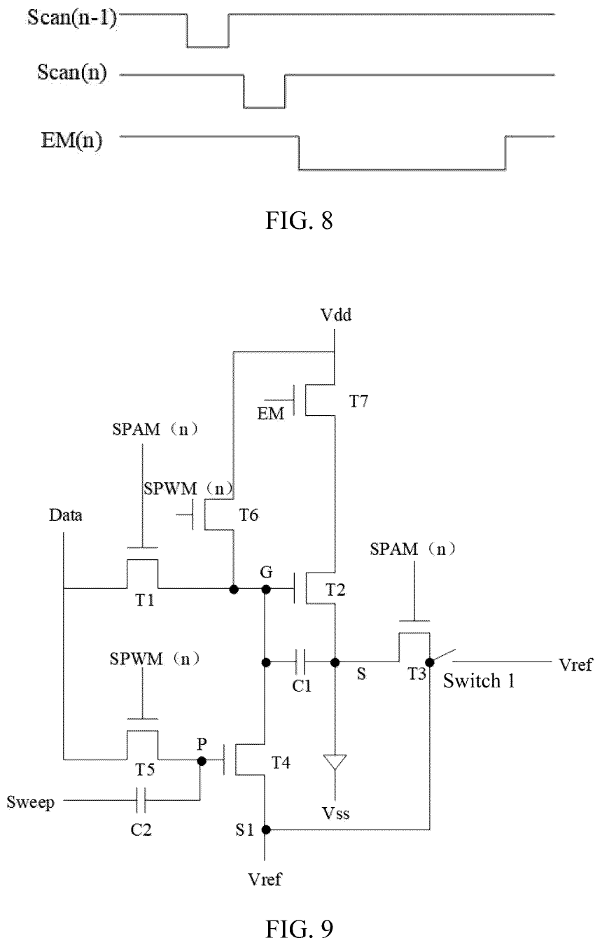

In addition, in the 8T1C pixel drive circuit shown in FIG. 7 and FIG. 8, the PAM (pulse amplitude modulation) driving performs gray cutting through the Data amplitude method. The light-emitting principle is analysed as follows:
1. Point B and G reset: T1 & T7 is turned on, Vb=Vdd, Vg=Vi;
2. Data writing and Vth compensation, anode reset: T5 & T8 & T3 are turned on, Vb=Vdata, Vg=Vdd+Vth, Va=Vss;
3. Light-emitting stage: EM(n) has high level, T2 & T6 are turned on, Vb drops from Vdata to Vi, Vb=Vdata−Vi, the potential of point G drops under the capacitor couple,

Vg=Vdd+Vth−ΔVb=Vdd+Vth−(Vdata−Vi),

Vgs−Vth=Vg−Vdd−Vth=Vi−Vdata,
working in saturation region, the driving current

$$I = k * {( Vgs - Vth )}^{2} = k * {( Vi - Vdata )}^{2} ,$$

$$k = \frac{1}{2} {μ}_{n} {C}_{ox} \frac{W}{L} ,$$

μₙ is a mobility of T4, Cₒₓ is a gate oxide layer capacitance per unit area of T4, W is a channel width of T4, L is a channel length of T4.

In one embodiment, the driving mode of the 3T1C and 8T1C pixel driving circuits in the previous embodiment is PAM driving, i.e., the constant current driving mode. However, due to the sorting characteristics and differences of LEDs themselves, the difference in luminous brightness between LEDs under the low current condition is large, which can easily cause uneven luminous brightness. Therefore, a PWM (Pulse Width Modulation) driving mode is often used under low grayscale condition, which maintains the actual operating current of the LED at a large value and achieves adjustment to the average luminous brightness by controlling the light-emitting time of LED. Therefore, the pixel driving circuit includes a pulse width modulation driving module and a pulse amplitude modulation driving module, and both the pulse width modulation driving module and the pulse amplitude modulation driving module are electrically connected to the light emitting unit 2. If the gray-level of the frame to be displayed by the light-emitting unit 2 is less than or equal to the preset gray-level (low gray-level), the pulse width modulation driving module in the pixel driving circuit drives the light-emitting unit 2 to emit the light. If the gray-level of the frame to be displayed by the light-emitting unit 2 is greater than the preset gray-level (high gray-level), the pulse amplitude modulation driving module in the pixel drive circuit drives the light-emitting unit 2 to emit the light, so the combined driving mode of the PAM driving under high gray-level+PWM driving under low gray-level are used.

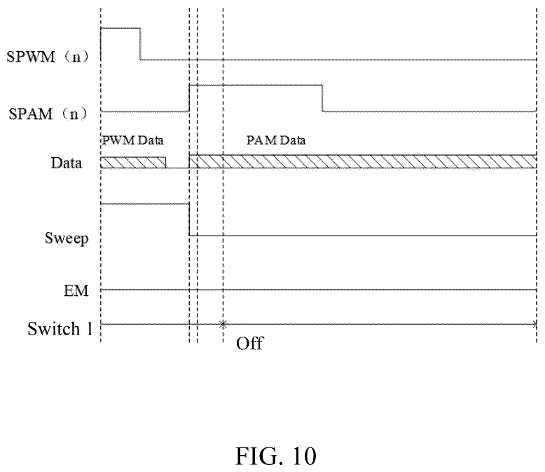

The 7T2C pixel driving circuit shown in FIG. 9 is the combined driving mode of PAM driving+PWM driving. The T2 detection process is shown in FIG. 10:

Step1: Writing PWM data line by line and turning off T4:
a. T5 & T6 are turn on, Vg=Vdd, Vp=PWM data, Vgs=PWM data−Vref=0V, T4 is turn off;

Step2: R/G/B write PAM data, S point initialization & S point charging & T2 Vth detection:
a. Sweep decreases, causing Vp to decrease and T4 keeping off;
b. PAM data is written, S point is initialized & charged, T1 & T3 are turned on, Vg=PAM data (R), Vs=Vref, switch 1 is turned off after 1 min, and the S point potential is charged from Vref to PAM data−Vth_T2;
c. Vth detection, wait until the S point potential rises steadily before connecting the external detection module, Vgs=PAM data−(PAM data−Vth_T2)=Vth_T2;
d. Completing the above Vth detection of R, and then repeating the above process to detect the Vth of GB.

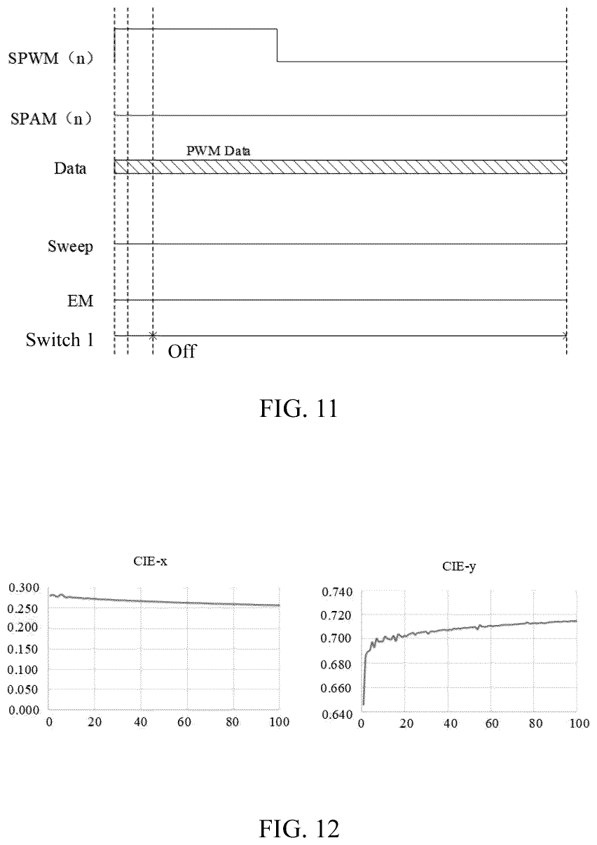

The T4 detection process is shown in FIG. 11:

Step1: R/G/B writes PWM data, S1 point initialization & S1 point charging & T4 Vth detection:
a. PWM data is written, S1 point is initialized & charged, T5 & T6 are turned on, Vg=Vdd, Vp=PWM data (R), Vs1=Vref, the switch 1 is turned off after 1 min, and the S1 point potential is charged from Vref to PWM data−Vth_T4;
b. Vth detection, wait until the S1 point potential rises steadily before connecting to the external detection module, Vgs=PWM data−(PAM data−Vth_T4)=Vth_T4;
c. Completing the above Vth detection of R, and then repeating the above process to detect the Vth of GB.

In the pixel drive circuit driven by the combination of high gray-scale PAM driving+low gray-scale PWM driving described in the present embodiment, the current of the light-emitting chip will have a larger span when the driving mode is switched, and the green light-emitting chip due to the properties of the material are prone to a large colour shift under large current span, as shown in FIG. 12, when the pixel drive circuit includes a pulse width modulation driving module and a pulse amplitude modulation driving module, both of the pulse width modulation driving module and the pulse amplitude modulation drive are all electrically connected to the third light-emitting chip 23, then the third light-emitting chip 23 is set as the green light-emitting chip, and two or more green light-emitting chips are used in series, which can ensure the interval span of the green light operation current is reduced on the premise that the luminous brightness is not deceased. That is, when the pulse width modulation drive is adjusted to the pulse amplitude modulation drive, the change value of the current flowing through the green light-emitting chip is less than or equal to the preset threshold, thereby remedying the colour shift problem of the frame caused by green light. The preset threshold is determined based on the design requirement, and no specific limitations are made in the present embodiment.

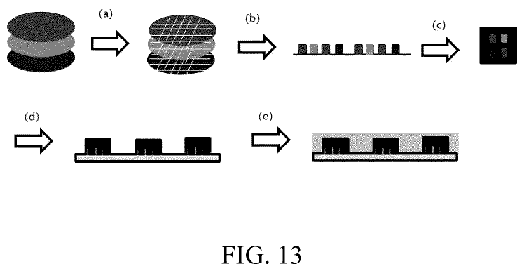

The MIP (Micro LED in Package) lamp bead design using RₙGₘB can significantly improve the pain points of the direct display application. From the perspective of preparation feasibility, since the microLED usually has a chip size below 50 μm, the MIP lamp bead package is generally not smaller than 200 μm. From the perspective of process feasibility, the design manner of the multiple chips using RₙGₘB in MIP is technically feasible. FIG. 13 is a schematic diagram of the preparation process of a direct display sample. Taking R₂GB as an example, the process (a) is to prepare microLED chips that meet the size requirements through chip epitaxial structures, and cut the chips into the required size by cutting. The process (b) is to transfer RGB three-colour microLED chips to the substrate containing circuits through mass transfer, and form the prepared MIP lamp beads through packaging and cutting manners. The MIP lamp beads contains 4 chips of RRGB. The process (c) is to transfer the MIP packaged lamp beads to the glass substrate through a solid crystal process, and the process (d) is to bake and cut the glass substrate sealant to form a finished product. The above processes are all based on the existing conventional processes and have mature mass production capabilities.

The present application aims to adopt the RₙGₘB design method for the pixel design of the direct display drive substrate circuit, and increase the proportion of LED chip power consumption in the system power consumption through the sub-pixel number ratio design, and reduce the proportion of the power consumption of the substrate driving TFT. On the other hand, the RₙGₘB design is used to reduce the driving current of the single R chip and G chip, improve the luminous instability of the R chip with the rising temperature, while also reducing the current range of the G chip and improving the colour shift of the G chip.

Table 1 shows the power consumption simulation results of the conventional RGB packaged MIP and RₙGₘB packaged MIP:
(1) The RGB is that the light-emitting unit 2 contains one red light-emitting chip, one green light-emitting chip and one blue light-emitting chip. When the voltage difference vale between VDD and VSS of the pixel drive circuit corresponding to the red light-emitting chip is 12.1V, and the current flowing through the red light-emitting chip is 47.274 mA, the power consumption of the red light-emitting chip and the entire circuit of the corresponding pixel drive circuit is 1.14E-03W.
(2) R2GB is that the light-emitting unit 2 contains two red light-emitting chips, one green light-emitting chip and one blue light-emitting chip. Compared with (1) RGB, (2) R2GB only adds one red light-emitting chip by parallel connection, (1) RGB and (2) R2GB have the same arrangement of the green light-emitting chip and the blue light-emitting chip. In (2) R2GB, when the voltage difference value between VDD and VSS of the pixel drive circuit corresponding to the red light-emitting chip is 12.44V, and the current flowing through the red light-emitting chip is 47.337 mA, the power consumption of the red light-emitting chip and the entire circuit of the corresponding pixel drive circuit is 5.90E-04W.
(3) The RGB light-emitting unit 2 contains one red light-emitting chip, one green light-emitting chip and one blue light-emitting chip. When the voltage difference value between VDD and VSS of the pixel drive circuit corresponding to the green light-emitting chip is 12.1V, and the current flowing through the green light-emitting chip is 20.95 mA, the power consumption of the green light-emitting chip and the entire circuit of the corresponding pixel drive circuit is 5.10E-04.
(4) RG2B is that the light-emitting unit 2 contains one red light-emitting chip, two green light-emitting chips and one blue light-emitting chip. Compared with (3) RGB, (4) RG2B only adds one green light-emitting chip by parallel connection. (3) RGB and (4) RG2B have the same arrangement of the red light-emitting chip and the blue light-emitting chip. In (4) RG2B, when the voltage difference value between VDD and VSS of the pixel drive circuit corresponding to the red light-emitting chip is 12.41V, and the current flowing through the green light-emitting chip is 20.9 mA, the power consumption of the green light-emitting chip and the entire circuit of the corresponding pixel drive circuit is 2.60E-04.

It can be seen from the data that by comparing the packaging manners (1) RGB with (2) R2GB, (2) R2GB adds one red light-emitting chip, the green light-emitting chip and the blue light-emitting chips in (1) RGB and (2) R2GB have the same arrangement, the current values flowing through the red light-emitting chips are similar, and the voltage difference value between VDD and VSS of the pixel drive circuit corresponds to the red light-emitting chip is similar. At this time, the red light-emitting chips in (1) RGB and (2) R2GB have the same luminous brightness, but the power consumption of the circuit of (2) R2GB is half of that of (1) RGB. Comparing the packaging manners (3) RGB and (4) RG2B, (4) RG2B adds one green light-emitting chip, the red light-emitting chips and the blue light-emitting chip in (3) RGB and (4) RG2B have the same arrangement, the current value flowing through the green light-emitting chip in (4) RG2B is half of that in (3) RGB, and the voltage difference value between VDD and VSS of the pixel drive circuit corresponding to the green light-emitting chip is similar. At this time, the red light-emitting chips in (3) RGB and (4) RG2B have the same luminous brightness, but the power consumption of the circuit of (4) RG2B is half that of (3) RGB. The power consumption used by the single MIP is reduced by about half under the condition that the same brightness is reached.

Table 1 Power consumption simulation

TABLE 1_sm_0001

| | Monochromatic | | Power |
|---|---|---|---|
| Packaging manner | current/mA | Voltage/V | consumption/W |
| \textcircled{1}RGB | 47.274 | 12.1 | 1.14E−03 |
| \textcircled{2}R₂GB | 47.337 | 12.44 | 5.90E−04 |
| \textcircled{3}RGB | 20.95 | 12.1 | 5.10E−04 |
| \textcircled{4}RG₂B | 20.9 | 12.41 | 2.60E−04 |

The present application provides a display device, which includes the display panel as described in any of the above embodiments.

In some embodiments, the first light-emitting chip provides the blue light, the second light-emitting chip provides the red light, and the third light-emitting chip provides the green light; the light-emitting unit includes at least the first light-emitting chip, at least the second light-emitting chip, and at least the third light-emitting chip.

In some embodiments, the circuit after the pixel driving circuit is connected to the light-emitting chip is set between a first voltage value and a second voltage value, and the maximum number of any one light-emitting chip in the light-emitting unit is positively related to the voltage difference value between the first voltage value and second voltage value, the first voltage terminal is VDD, and the second voltage terminal is VSS.

In some embodiments, the number of the second light-emitting chip in the light-emitting units is 2-6.

In some embodiments, the number of the third light-emitting chip in the light-emitting units is 2-4.

In some embodiments, the light-emitting unit further includes a substrate and a packaging layer, the first light-emitting chip, the second light-emitting chip and the third light-emitting chip are bound to the substrate, and the packaging layer covers the first light-emitting chip, the second light-emitting chip and the third light-emitting chip.

In some embodiments, each of the light-emitting chips in the LED package module shares a common cathode or a common anode.

In some embodiments, the first light-emitting chip, the second light-emitting chip and the third light-emitting chip are alternately arranged in the light-emitting unit.

In some embodiments, the pixel driving circuit includes a driving module, a switch module and a charge storage module, and the driving module is connected in series with the light-emitting chip having the same colour in the light-emitting unit between the first voltage terminal and the second voltage terminal, and the driving module are electrically connected to the charge storage module, the first end of the switch module is connected to the scan signal, the second end of the switch module is connected to the data signal, and the third end of the switch module is connected to the driving module and the charge storage module.

In some embodiments, the pixel driving circuit further includes a compensation module electrically connected to the driving module and the charge storage module. The compensation module is used to maintain the voltage at two ends of the light-emitting chip electrically connected to the pixel driving circuit constant.

In some embodiments, the pixel driving circuit includes a pulse width modulation driving module and a pulse amplitude modulation driving module, and both of the pulse width modulation driving module and the pulse amplitude modulation driving module are electrically connected to the third light-emitting chip, the third light-emitting chip is set as the green light-emitting chip.

In some embodiments, if the gray-level of the frame to be displayed by the light-emitting unit is less than or equal to the preset gray-level, the pulse width modulation driving module drives the third light-emitting chip to emit light; if the gray-level of the frame to be displayed by the light-emitting unit is greater than the preset gray-level, the pulse amplitude modulation driving module drives the third light-emitting chip to emit light; when the pulse width modulation driving is adjusted to the pulse amplitude modulation driving, the change value in the current flowing through the third light-emitting chip is less than or equal to the preset threshold.

In some embodiments, the number of the pixel driving circuits connected to the light-emitting unit is the same as the number of the colour types of the light-emitting chips contained in the light-emitting unit.

In some embodiments, the light-emitting unit further includes a fourth light-emitting chip, and the fourth light-emitting chip provides a white light.

In the display panel and the display device provided by the embodiments of the present application, a plurality of the light-emitting chips having at least one colour are provided in the light-emitting unit, and are connected in series and then electrically connected to the pixel driving circuit. Compared with the case that only one light-emitting chip is connected, the number of components connected in the pixel drive circuit when the plurality of the light-emitting chips are connected is increased, the current is reduced, and the proportion of the power consumption of the light-emitting chip portion is increased in the panel power consumption, reducing the overall power consumption of the panel.

In the above embodiments, each embodiment has its own emphasis in description. For the parts that are not described in detail in a certain embodiment, please refer to the relevant descriptions of other embodiments.

Each of the technical features of the above embodiments may be combined in any way. To simplify the description, not all possible combinations of the respective technical features in the above embodiments are described. However, as long as there is no contradiction in the combination of these technical features, all possible combinations should be considered to be within the scope described in the present specification.

The above is a detailed introduction to the display panel and the display device provided by the embodiments of the present application. Specific examples are used herein to illustrate the principles and implementations of the present disclosure. The description of the above embodiments is only used to help understand the method and the core idea thereof in present disclosure; mean, for those skilled in the art, there will be changes in the specific implementation and application scope according to the idea of the present disclosure. In summary, the content of the present description should not be understood as limit to the present disclosure.

1. A display panel, comprising:
an array substrate, wherein a plurality of pixel driving circuits are provided on the array substrate;
a plurality of light-emitting units, wherein the plurality of the light-emitting units are provided in an array on the array substrate, each of the light-emitting units comprises a plurality of light-emitting chips, the plurality of light-emitting chips comprise a first light-emitting chip, a second light-emitting chip and a third light-emitting chip, the first light-emitting chip, the second light-emitting chip and the third light-emitting chip have colours different from each other; a number of the light-emitting chips contained in any one of the light-emitting units is greater than a number of colour types of the light-emitting chips; light-emitting chips having a same colour in each of the light-emitting units are connected in series, and the light-emitting chips having the same colour in each of the light-emitting units are electrically connected to one of the pixel driving circuits;
wherein the first light-emitting chip provides a blue light, the second light-emitting chip provides a red light, and the third light-emitting chip provides a green light; each of the light-emitting units comprises one the first light-emitting chip, at least one the second light-emitting chip, and at least one the third light-emitting chip;
wherein the first light-emitting chip, the second light-emitting chip and the third light-emitting chip in each of the light-emitting units are alternately arranged.

2. The display panel of claim 1, wherein the light-emitting units are connected between a first voltage terminal and a second voltage terminal, and a maximum number of any one of the light-emitting chips in the light-emitting units is positively related to a voltage difference value between the first voltage terminal and the second voltage terminal, the first voltage terminal is VDD, and the second voltage terminal is VSS.

3. The display panel of claim 2, wherein a number of the second light-emitting chip in each of the light-emitting units is 2-6.

4. The display panel of claim 2, wherein a number of the third light-emitting chip in each of the light-emitting units is 2-4.

5. The display panel of claim 1, wherein each of the light-emitting units further comprise a substrate and an encapsulation layer, and the first light-emitting chip, the second light-emitting chip and the third light-emitting chip are bound to the substrate, the encapsulation layer covers the first light-emitting chip, the second light-emitting chip and the third light-emitting chip.

6. A display panel, comprising:
an array substrate, wherein a plurality of pixel driving circuits are provided on the array substrate;
a plurality of light-emitting units, wherein the plurality of the light-emitting units are provided in an array on the array substrate, each of the light-emitting unit comprises a plurality of light-emitting chips, the plurality of light-emitting chips comprise a first light-emitting chip, a second light-emitting chip and a third light-emitting chip, the first light-emitting chip, the second light-emitting chip and the third light-emitting chip have colours different from each other; a number of the light-emitting chips contained in any one of the light-emitting units is greater than a number of colour types of the light-emitting chips; light-emitting chips having a same colour in each of the light-emitting units are connected in series, and the light-emitting chips having the same colour in each of the light-emitting units are electrically connected to one of the pixel driving circuits.

7. The display panel of claim 6, wherein the first light-emitting chip provides a blue light, the second light-emitting chip provides a red light, and the third light-emitting chip provides a green light; each of the light-emitting units comprise one the first light-emitting chip, at least one the second light-emitting chip, and at least one the third light-emitting chip.

8. The display panel of claim 7, wherein the light-emitting units are connected between a first voltage terminal and a second voltage terminal, and a maximum number of any one of the light-emitting chips in the light-emitting units is positively related to a voltage difference value between the first voltage terminal and the second voltage terminal, the first voltage terminal is VDD, and the second voltage terminal is VSS.

9. The display panel of claim 8, wherein a number of the second light-emitting chip in each of the light-emitting units is 2-6.

10. The display panel of claim 8, wherein a number of the third light-emitting chip in each of the light-emitting units is 2-4.

11. The display panel of claim 7, wherein each of the light-emitting units further comprise a substrate and an encapsulation layer, and the first light-emitting chip, the second light-emitting chip and the third light-emitting chip are bound to the substrate, the encapsulation layer covers the first light-emitting chip, the second light-emitting chip and the third light-emitting chip.

12. The display panel of claim 11, wherein each of the light-emitting chips in each of the light-emitting units share a common cathode or a common anode.

13. The display panel of claim 6, wherein the first light-emitting chip, the second light-emitting chip and the third light-emitting chip in each of the light-emitting units are alternately arranged.

14. The display panel of claim 6, wherein each of the pixel driving circuits comprises a driving module, a switch module and a charge storage module, the driving module is connected in series with the light-emitting chips having the same colour in the light-emitting units, and the driving module is electrically connected to the charge storage module, a first end of the switch module is connected to a scan signal, a second end of the switch module is connected to a data signal, and a third end of the switch module is connected to the driving module and the charge storage module.

15. The display panel of claim 14, wherein each of the pixel driving circuits further comprises a compensation module electrically connected to the driving module and the charge storage module, and the compensation module is used to maintain a voltage value at two ends of the light-emitting chips electrically connected to each of the pixel driving circuits constant.

16. The display panel of claim 6, wherein each of the pixel driving circuits comprises a pulse width modulation driving module and a pulse amplitude modulation driving module, the pulse width modulation driving module and the pulse amplitude modulation driving module are both electrically connected to the third light-emitting chip, and the third light-emitting chip is set as a green light-emitting chip.

17. The display panel of claim 16, wherein if a gray-level of a frame to be displayed by the light-emitting units is less than or equal to a preset gray-level, the pulse width modulation driving module drives the third light-emitting chip to emit light; if the gray scale of the frame to be displayed by the light-emitting units is greater than the preset gray scale, the pulse amplitude modulation driving module drives the third light-emitting chip to emit light; when the pulse width modulation driving module is adjusted to the pulse amplitude modulation driving module, a change value of a current flowing through the third light-emitting chip is less than or equal to a preset threshold.

18. The display panel of claim 6, wherein a number of the pixel driving circuits connected to each of the light-emitting units is same as a number of colour types of the light-emitting chips contained in each of the light-emitting units.

19. The display panel of claim 6, wherein each of the light-emitting units further comprises a fourth light-emitting chip, and the fourth light-emitting chip provides a white light.

20. A display device, wherein the display device comprises the display panel comprising:
an array substrate, wherein a plurality of pixel driving circuits are provided on the array substrate;
a plurality of light-emitting units, wherein the plurality of the light-emitting units are provided in an array on the array substrate, each of the light-emitting units comprises a plurality of light-emitting chips, the plurality of light-emitting chips comprise a first light-emitting chip, a second light-emitting chip and a third light-emitting chip, the first light-emitting chip, the second light-emitting chip and the third light-emitting chip have colours different from each other; a number of the light-emitting chips contained in any one of the light-emitting units is greater than a number of colour types of the light-emitting chips; light-emitting chips having a same colour in each of the light-emitting units are connected in series, and the light-emitting chips having the same colour in each of the light-emitting units are electrically connected to one of the pixel driving circuits;
wherein the first light-emitting chip provides a blue light, the second light-emitting chip provides a red light, and the third light-emitting chip provides a green light; each of the light-emitting units comprises one the first light-emitting chip, at least one the second light-emitting chip, and at least one the third light-emitting chip;
wherein the first light-emitting chip, the second light-emitting chip and the third light-emitting chip in each of the light-emitting units are alternately arranged.
